(19) United States
(12) Patent Application Publication
(10) Pub. No.: US 2010/0065103 A1
(43) Pub. Date: Mar. 18, 2010

(54) Flux Tailored Converter of Radiatio

(76) Inventor: Rodolfo BERTOCCHI, Herzeliya (IL)

Correspondence Address: SOROKER-AGMON ADVOCATE AND PATENT ATTORNEYS, NOLTON HOUSE, 14 SHENKAR STREET, HERZELIYA PITUACH, 46725, IL

(21) Appl. No.: 12/550,440

(22) Filed: Aug. 31, 2009

(30) Foreign Application Priority Data
Sep. 16, 2008 (ES) P 200802686

(51) Int. Cl. H01L 31/052

(52) U.S. Cl. 136/246

(57) ABSTRACT

The present invention discloses a system for converting incident radiation energy into electric power. A cavity, whose wall is clad with a mixture of photon conversion devices and specularly reflective coatings, is irradiated by concentrated radiation energy. The shape of said cavity is tailored to the irradiation distribution, so that a generally uniform surface radiation flux is achieved for optimal conversion into electricity by a plurality of photon conversion devices; the balance being absorbed and removed as heat in a cooling fluid. Specular reflective coatings propagate scattered radiation further into said cavity for eventual conversion into electricity. An integrating unit combines and maximizes the output power from individual photon conversion devices into a single output feed.

### TECHNICAL FIELD OF INVENTION

The present invention relates generally to the field of energy conversion, and more particularly to systems converting concentrated radiation energy into electric power.

### BACKGROUND OF THE INVENTION

Photon conversion devices are commonly used to convert incident radiation energy directly into electricity for electrically powered terrestrial and space applications. The quest for reducing greenhouse gas emissions, partly associated with the generation of electricity, requires that the efficiency of photon conversion device systems be significantly increased in order to economically compete with conventional fossil fuel based electricity generating technologies.

Terrestrial visible light energy is essentially electromagnetic radiation emitted from a black body at a temperature of 5800 K. The wavelength spectrum of the said incident black body radiation energy ranges from the ultra-violet at 300 nm to the far infrared at 3 um, with the maximum radiation intensity at visible wavelengths of 500-600 nm. In accordance with the practice of quantum mechanics theory, radiation energy consists of photons, each photon having energy inversely proportional to its wavelength, making “blue” photons more energetic than “red” photons.

Photon conversion device may be manufactured from different semiconductor materials. Each semi-conducting material having a specific bandgap energy converting solely the energy of the incident photons with energy levels higher than the bandgap energy of said semi-conducting material into electricity. The energy of photons with energy levels different than the photon conversion device's bandgap energy is either converted into heat or scattered. Typically, the bandgaps of semi-conducting materials are narrow with a distinct peak efficiency wavelength. No commercial semi-conducting material spans efficiently the entire radiation spectrum originating from a 5800 K black body radiation. From the aforesaid it is obvious that a single bandgap photon conversion device will have a low radiation to electricity conversion efficiency.

Present art achieves the goal of converting a maximum amount of incident radiation energy into electricity by stacking photon conversion devices with different bandgap levels; either monolithically or mechanically. A monolithic multi-junction, photon conversion device has a measured conversion efficiency exceeding 25% at normal terrestrial irradiation. U.S. Pat. No. 6,281,426, which is incorporated by reference herein, describes the structure of possible monolithic multi-junction devices.

However, in accordance with classic electric theory, the useful electric power produced by a photon conversion device is the product of the generated voltage and current, which is a function of both radiation intensity and bandgap energy. Stacked photon conversion device configurations obey the laws of electricity, and are therefore either current or voltage limited; requiring very careful matching of the different layers' quantum properties. Still, perfect matching is very difficult to achieve, particularly for cells having three or more internal electrical junctions, resulting in inherent conversion losses. Additionally, in a multi junction monolithic photon conversion device the different layers are not entirely transparent to the non-absorbed photons, and further losses are induced into the system. Mechanically stacked cells can circumvent some of the drawbacks of the monolithic cells, but still suffer from losses induced by the mismatch of the individual photon conversion device's electrical properties.

Additionally, the efficiency of a photon conversion device is approximately proportional to the logarithm of the radiation intensity up to a certain radiation flux level where the internal resistive losses exceed the gain due to increased photonic flux. Present art has shown that increasing the radiation concentration by a factor of 500 may augment the laboratory measured conversion efficiency of a multi junction photon conversion device from 25% to over 35%. However, the use of concentrated radiation energy requires a means to generate uniform irradiation of the illuminated photon conversion device, or matrix of connected photon conversion devices, otherwise the most weakly irradiated photon conversion device may limit the power output of the entire circuit, rendering the concept of conversion gains due to radiation concentration ineffective. Various optical means are available for generating a uniform irradiation. Unfortunately, said means frequently introduce significant secondary optical losses that may exceed the intended conversion efficiency gains.

Furthermore, the requirement of evacuating the generated current from a photon conversion device dictates that approximately 20-40% of the device's illuminated footprint area be dedicated to electrical conduction, typically from one to four of the device's circumferential rims. Thus, a flat matrix of a multitude of connected photon conversion device will suffer from a very low area efficiency, since the incident radiation flux impinging the non photonic active electrical contact area is lost, being either reflected or converted into heat.

### EXPLANATION OF THE INVENTION

Accordingly, it is a general object of the present invention to provide a more efficient and economical photon conversion device system than has been heretofore available.

It is a specific object of the present invention to provide a tailored volumetric, broad spectrum, photon conversion device system that converts a maximum amount of impinging concentrated radiation energy into electricity while simultaneously minimizing re-radiation losses.

According to some embodiments of the invention, the system for converting incident radiation into electricity may comprise a concentrator having at least one cambered reflective surface.

According to some embodiments of the invention, the concentrator may be as described in U.S. Pat. No. 7,156,531 by Bertocchi Rudi disclosing a parabolic concentrator, and is herein incorporated by reference to the disclosure of this application.

A further specific object of the present invention is to store the excess energy, which has not been converted into electricity, as heat in a circulating cooling fluid.

A still further specific object of the present invention is to use the stored latent energy in the circulating cooling fluid as heat in auxiliary applications such as water desalination, thermo-electrical electricity generation, hot water for personal/industrial use, space heating, general process heat, etc. Other objects and advantages will become readily apparent by virtue of the description hereinafter, and in part will become apparent to those skilled in the art upon examination of the following or may be learned by the practice of the invention. The objects and the advantages may be realized and attained by means of the instrumentalities and in combinations particularly pointed out in the appended claims.

The present invention thus provides in a first aspect, a flux tailored volumetric photon conversion device system comprising:
a radiation flux concentrator, either imaging or non-imaging, continuously providing highly concentrated radiation energy.
a support structure for rigidly attaching the tailored volumetric cavity module to aforesaid radiation concentrator at an optimal location. The said structure may be comprised of tubes, allowing fluids and electrical cables to be conveyed to an interface on the module.
a means for quickly disconnecting the cavity module from the support structure for the purpose of removal.
a hollow shelled, three dimensional axis-symmetric body comprising of an inner cavity and an aperture providing ingress for the incident concentrated radiation energy. The geometry of said cavity being so defined that the resulting axial radiation flux distribution on the walls of said cavity is simultaneously azimuthally, and within delimited meridian bands, uniform. The axial cross sectional area of said cavity generally contracts in accordance with the axial flux distribution as a means to match the specific circumferential area to the local incident radiation flux, thus achieving the intended uniform radiation flux distribution on the irradiated walls. The slenderness ratio of said tailored cavity, defined as the ratio of the cavity length to the ingress aperture diameter, exceeds unity.
a plurality of photon conversion devices with different bandgap energies, either monolithically or mechanically stacked, cladding the radiation exposed surface of the aforesaid flux tailored cavity.
a specularly reflective, encapsulating and electrically conductive material clad to the photonic inactive area of the irradiated photon conversion device's surface. Said material being simultaneously dedicated to the evacuation of the generated electricity and to further propagate by reflection into the cavity the impinging and scattered incident radiation for eventual absorption by extra photon conversion devices.
a means for connecting the aforesaid photon conversion devices, within uniformly irradiated delimiting meridian bands, in an electrical circuit purposely determined for minimizing energy losses due to electrical mismatching of the interconnected photon conversion devices.

The present invention further provides a means for protecting the tailored cavity and said cavity's photon conversion device clad walls from excessive exposure to adverse weather conditions such as: rain, hail, sand storms etc., by spanning the ingress aperture with a radiation transparent window, the perimeter and surface of said window being sealed against the forced ingress into the cavity of fluids or particles or a combination thereof.

To achieve the aforementioned in accordance with the purposes of the present invention, as embodied and described henceforth, the flux tailored cavity is oriented in relation to the incident concentrated radiation so that the ingress aperture plane is at a location in the close vicinity of maximum radiation concentration. The size of the ingress aperture being optimized with regards both to minimum re-radiation losses from the irradiated volumetric cavity and to maximum interception of incident radiation.

The inner surface of the mono apertured, tailored, volumetric converter body comprises a generally contracting axial cross sectional surface distribution. Said surface distribution being defined so that the resulting radiation flux upon the cavity's circumferential wall, due to the ingress of the incident concentrated radiation energy, is approximately azimuthally, and piecewise axially, uniform.

The fraction of the said tailored cavity module's inner irradiated surface, which is characterized by a quasi uniform radiation flux, is clad with a plurality of photon conversion devices, having a combination of discrete bandgap energies spanning the spectrum of the incident radiation energy, said photon conversion devices being either monolithic or mechanically stacked.

The requirement for evacuating the generated electricity prevents the active area of the photon conversion device to extend to its physical border. The balance between the photonic active area and the device's physical area is designated to the purpose for electrical contacts and circuitry. In the embodiment of the present invention, the said photonic inactive area is clad with a reflective material for the purpose of re-directing the scattered radiation energy further into the tailored cavity for eventual conversion into electricity by additional photon conversion devices in the cavity of said module.

The fraction of the incident radiation that is neither converted into electricity nor lost through the entrance aperture as re-radiation is converted into heat. In order not to exceed the photon conversion device's maximum limiting operating temperature, the generated heat has to be forcibly conducted away by a circulating cooling fluid. The incremental heat content of the said cooling fluid may be subsequently exploited for additional thermodynamic or thermoelectric applications, thus augmenting the total system efficiency with regard to total extracted energy conversion from the incident radiation energy.

The open circuit voltage of the said photon conversion devices is approximately a logarithmic function to the incident radiation flux. Present art practice of a simple serial connection of illuminated photon conversion devices experience an inherent voltage limitation by the lowest voltage photon conversion device in the circuit, hence annulling power gains by higher individual voltages of other photon conversion devices in the aforesaid circuit. In the present invention this detrimental limitation is obviated by all cells in the circuitry being subjected to quasi uniform incident flux, thus generating currents at uniform voltage levels. Furthermore, only photon conversion devices having an essentially equal open circuit voltage are mutually interconnected in series and further fed to a unique switching and combining unit. The open circuit voltage of each photon conversion device feed may be monitored by a local processing unit. Said processing unit may utilize an optimization power maximizing algorithm for determining the internal connecting schedule of inputted photon conversion device feeds to a single output feed by means of an array of switching devices under its control. The integrated, power maximized, DC output of the switching and combining unit may be connected to a high efficiency DC-AC inverter for generating alternating current electricity matched to the requirements of the local or national electrical network grid for eventual distribution to the intended end user.

The invention will be best understood when read in conjunction with the accompanying drawings. The particulars are shown by example and for the purpose of illustrating the preferred embodiment of the present invention. Other advantages of the present invention relative to the present art will be apparent from the particular description of the preferred embodiment, the description taken with the drawings making apparent to those skilled in the art how the several forms of the invention may be implemented in practice.

### BRIEF DESCRIPTION OF THE DRAWINGS

Reference will now be made to the accompanying drawings, which illustrate the preferred embodiment of the invention and wherein:

FIG. 1, is a simplified side section view of the principal components of the present invention;

FIG. 2, on coordinates of relative energy flux and fractional radius of ingress aperture, is a diagram depicting the spatial energy flux distribution on the ingress aperture plane of the cavity generated by a primary parabolic concentrator;

FIG. 3, on coordinates of fractional cavity length and normalized direct irradiation flux, is a diagram depicting the axial radiation energy flux distribution on the walls of a cylindrical cavity (prior art);

FIG. 4, on coordinates of fractional cavity length and normalized direct irradiation flux, is a diagram simultaneously depicting the axial radiation energy flux distribution on the walls of a tailored cavity, and the cavity radius match to the incident wall influx;

FIG. 5, is a detailed side section view of a single installed photon conversion device in the flux tailored cavity depicting the mechanism of radiation energy exchange, electric energy evacuation and heat conduction;

FIG. 6, is a detailed side section view of the principal components of the flux tailored volumetric cavity, the photon conversion device clad inner surface and the different modes of the cavity-radiation interaction;

FIG. 7, is a schematic section view of the photon conversion device clad flux tailored cavity having photonic active areas within specific delimited energy bandgaps. Said photon conversion devices are windowed with an alternatively transmissive or reflective substrate, the transmissivity matched to the photon conversion devices' bandgap energy;

FIG. 8, is a general system operational scheme depicting the preferred layout for maximizing radiation to electricity conversion efficiency, connection to the electrical network and remote system monitoring.

### DETAILED DESCRIPTION OF THE PREFERRED EMBODIMENT

The present invention discloses a system 1000 and a flux tailored volumetric converter 100 for converting concentrated incident radiation energy 12 into electricity.

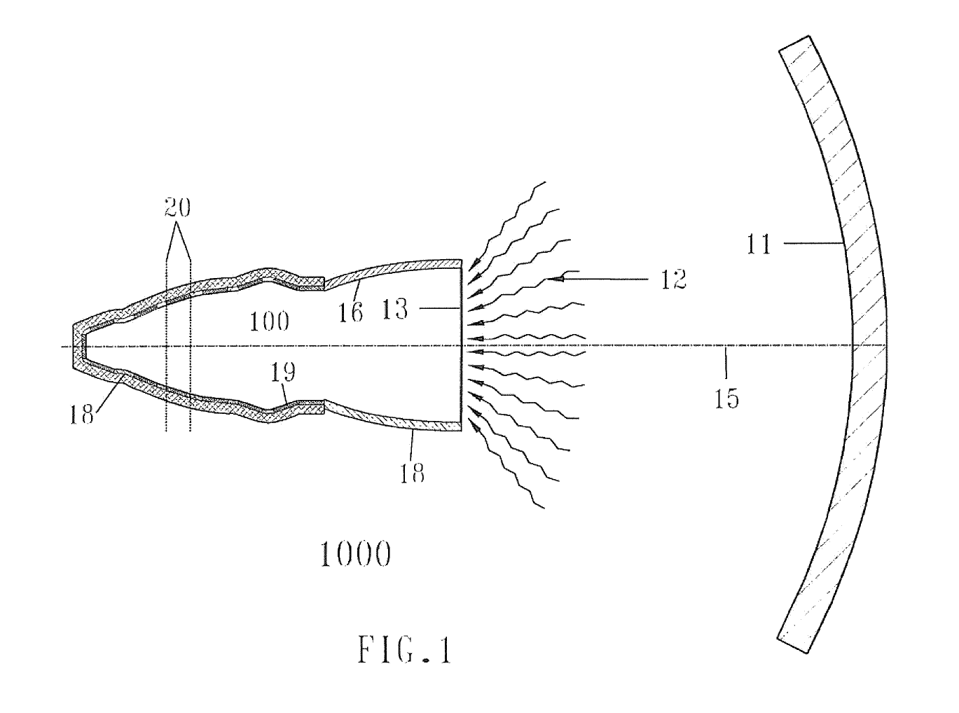

Referring now to the drawings and firstly to FIG. 1, which is a simplified side section view showing the flux tailored radiation converter 100 constructed in accordance with a preferred embodiment of the present invention.

The concentrated radiation energy 12 is first focused by a primary concentrator 11. Ingress of the concentrated radiation energy 12 into the cavity of the converter is by means of a mono ingress aperture 13, which may be windowed. Said window may have a selectively transmissive/reflecting optical coating permitting ingress only to the photonic inductive fraction of the incident radiation spectrum into said cavity. The diameter, approximately the cavity's largest, and axial location of said ingress aperture is optimized for capturing a maximum fraction of the incident radiation energy whilst minimizing the re-radiation losses of the irradiated cavity.

The converter 100 is a body of revolution whose axis 15 may coincide with the radiation concentrator's optical axis. The converter's optimized, flux tailored, cross section distribution is obtained by means of numerical ray tracing analysis. The resulting defining curve of said body of revolution, whilst generally contracting and having a slenderness ratio of at least unity, may consist of a local combination of rectilinear, contracting or expanding segments, the mixture of said segments being a result of the numerical optimization for maximum radiation conversion at minimum re-radiation losses.

The inner surface of the converter cavity is a combination of specularly reflective 18 and photonic active areas 19, said photonic active areas may be clad with photon conversion devices.

The defining curve 16 of said cavity expands and contracts as a means to achieve piecewise closely uniform axial influx distribution on the photonic active circumferential surfaces between sets of two delimiting meridian planes 20. The converter's specularly reflective segments 18 are axially distributed with a local specific inclination generating both the sought surface flux distribution whilst further propagating the re-reflected radiation into the converter for eventual absorption, thus maximizing cavity's conversion efficiency and minimizing its re-radiation losses.

A group of interconnected photon conversion devices 19 constitute the photonic active cavity surface between delimiting meridian planes 20. In each of the said groups the occupying photon conversion devices may be either monolithic or mechanically stacked. The aforementioned photon conversion devices may be bonded to the underlying surface by means of a thermally conductive substance or a thermally and electrically conductive substance. Electric interconnection of the plurality of said photon conversion devices is by means of electrical conductive pathways. For one electrical pole, one such a pathway may be the conductive surface of the cavity, which may have a conductive coating applied to it or be manufactured in part or in whole from an electric conductive substance, which may be copper or aluminium.

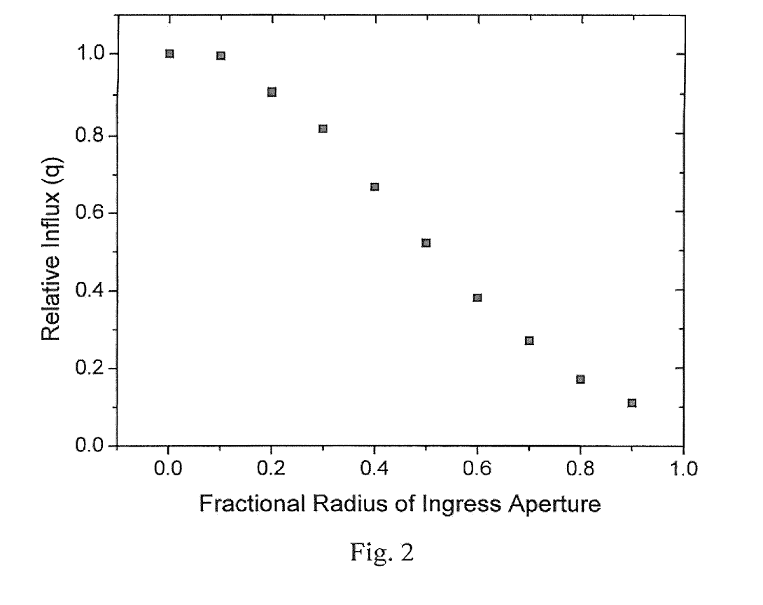

Referring now to FIG. 2, which depicts on coordinates of relative energy influx and fractional ingress aperture, the obtained quasi-Gaussian spatial energy distribution on the ingress aperture by a primary concentrator. Said flux distribution being numerically calculated by means of a ray-tracing code; accounting for the concentrator's angular spread of the incident radiation source and optical errors of the concentrator. By inspection, it is evident that the energy flux impinging upon the ingress aperture is highly non-uniform and wholly unsuited for the direct and efficient conversion into electricity by photon conversion devices. It is the purpose of the present invention to remedy this shortcoming, and by means of the preferred embodiment spatially transform the non-uniform irradiation into uniform circumferential and axial radial radiation bands. Said radiation bands uniformly irradiate the installed photon conversion devices, thus maximizing their radiation-to-electricity conversion efficiency.

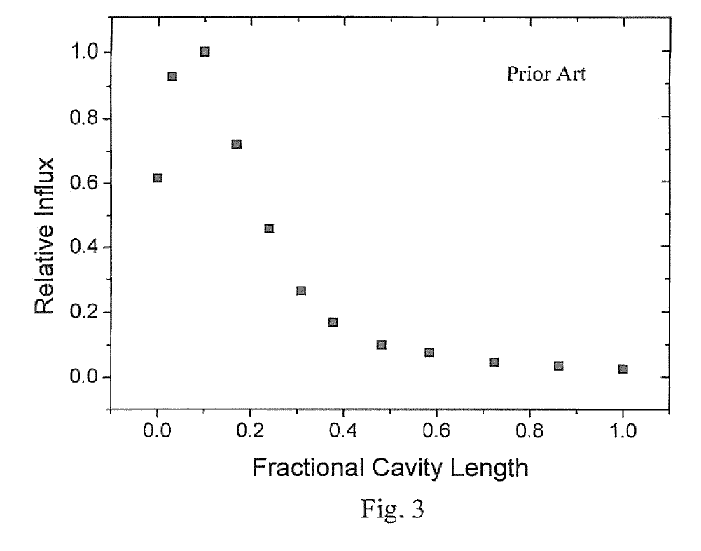

Referring now to FIG. 3, which depicts on coordinates of relative influx and fractional cavity length the flux distribution, resulting from the ingress aperture flux distribution defined in FIG. 2, on the circumferential wall of a cylindrical cavity, whose length is twice its diameter, located rear of the ingress aperture (prior art). From FIG. 3. it is obvious that the incident flux distribution on the walls of a cylindrical cavity is axially highly non-uniform. The foremost fraction of the cylinder cavity is most intensely illuminated, while practically the half rearmost part of the cylinder intercepts no direct irradiation and is essentially dark. Furthermore, the flux distribution of the region close to the ingress aperture exhibits strong gradients; increasing rapidly to a maximum at about 15% axial distance and then inversely exponentially decaying. Undoubtedly, should the walls of the cylindrical cavity be clad with an axially uniform distribution of photon conversion devices, the radiation to electrical conversion efficiency would be highly unsatisfactory. The photon conversion devices in the anterior region would experience a very strong irradiation with prohibitive internal electrical resistance losses and possible structural damage due to overheating, while the photon conversion devices in the posterior region would be poorly irradiated with only a minor electricity generating capability. It is the purpose of the present invention to remedy the faults of the prior art; achieving a piecewise uniform wall flux distribution by tailoring the irradiated cavity's cross sectional area to the local incident flux distribution and to further propagate all scattered radiation into the cavity for eventual conversion into electricity with a minimum of re-radiation losses.

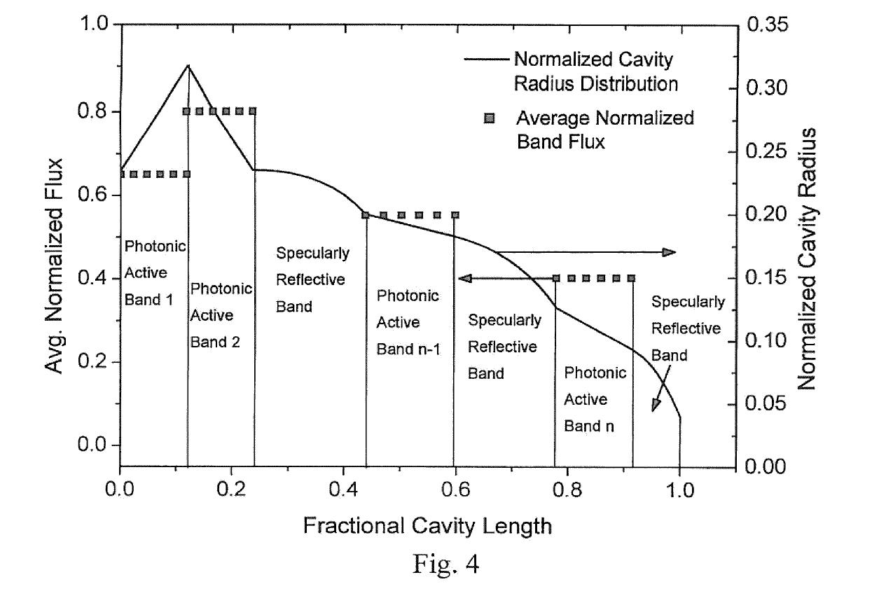

Referring now to FIG. 4, which depicts on coordinates of average normalized influx and fractional cavity length, the cavity wall's axial flux distribution of the preferred embodiment.

FIG. 4 further depicts generally the cavity's axial radius distribution, correlating to the axial flux distribution; the eventual specific cavity geometry being tailored to each application depending on the combined radiative characteristics of the irradiation source and the radiation concentrating system.

FIG. 4 depicts the principle of how with an axially varying cavity radius, combined with a mixture of photonic active and specularly reflective segments, it is possible to achieve, within limiting meridian bands, a generally uniform axial flux distribution. The extent and amount of the cavity's photonic active and specularly reflective bands is determined by means of numerical analysis employing statistical ray tracing; each design case being exclusively defined by the irradiation source and concentrating apparatus.

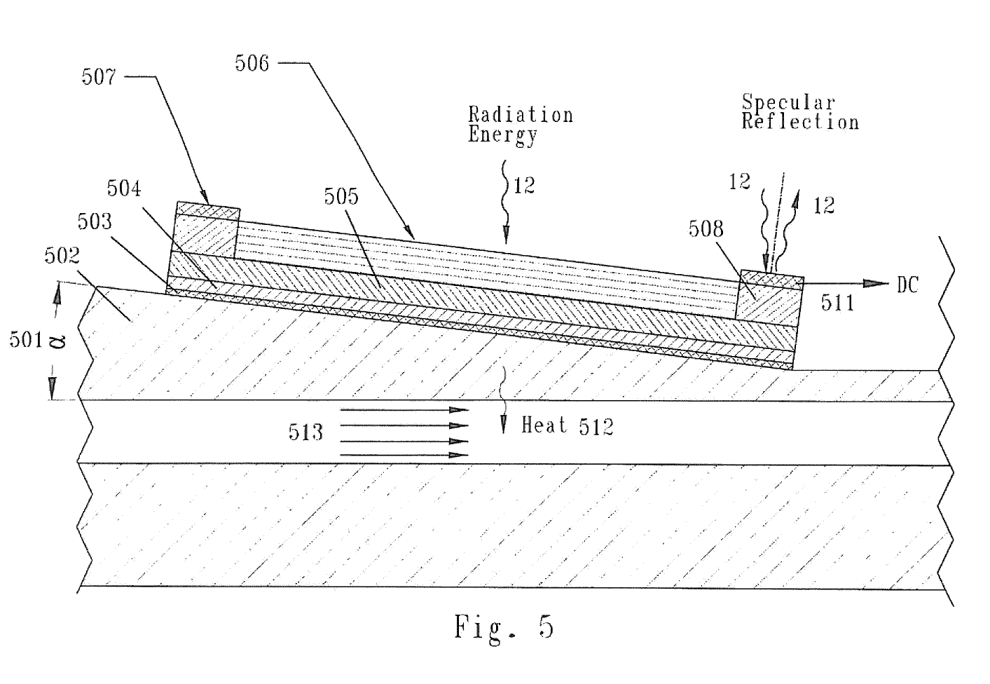

FIG. 5 depicts the energy exchange mechanism between a photon conversion device, the impinging radiation energy and the structural housing. The photon conversion device is clad to the machined surface of the structural cavity housing 502 at an incidence angle 501 which is determined by numerical analysis, said incidence angle may vary continuously along the longitudinal axis of the tailored cavity and its axial variation is exclusive for each combination of incident radiation source and concentrating configuration. The photon conversion device's base substrate 505 is bonded to the structural housing by means of a thin thermally conductive layer 503. Said layer may be either electrically conductive or insulating depending on the polarity of the substrate's electrically conducting metal contact 504. An electric contact 508, with opposite polarity to the substrate's contact, is located at the photon conversion device's rim. Said contact typically occupies either one, two or all four photon conversion device edges. A specularly reflective and electrically conductive metal frame 507 clads the top surface of the photon conversion device's top contact 508 and may be used to evacuate the generated electrical Direct Current (DC) energy 511 and to interconnect adjacent photon conversion devices.

Incident radiation 12, which may either originate from the external concentrator 11 or from internal re-reflections originating within the tailored cavity itself, illuminates the photon conversion device. Said irradiation impinges either the local photonic active area 506 or the specularly reflective metal frame 507. A certain fraction of the irradiation is by means of quantum mechanics effects directly converted into DC electricity 511 while the balance is either scattered at the top surface interface or converted into heat energy 512. Imperatively, the generated heat energy must be removed from the photon conversion device or it may be subjected to catastrophic structural failure due to overheating. In the preferred embodiment, a flowing cooling fluid is utilized to cool the photon conversion device and to maintain its temperature within allowable operating ranges. The generated heat 512 is conducted through the mutually thermally conductive adhesion layer 503 and cavity housing 502 into the cooling fluid 513, where it is absorbed and conveyed to a remote heat exchanger.

The fraction of the irradiation that impinges the specular metal contact 507 is specularly reflected in accordance with Snell's law. It is the specific intention of the present invention that by means of tailoring the local slope 501, the reflected radiation is further directed towards additional arrays of photon conversion devices for eventual absorption. A small fraction of the reflected radiation may after a number of reflections be re-radiated back through the ingress aperture without undergoing absorption. Diligent design ensures that the lost fraction is in the order of a few percent of the total direct radiation flux through the ingress aperture.

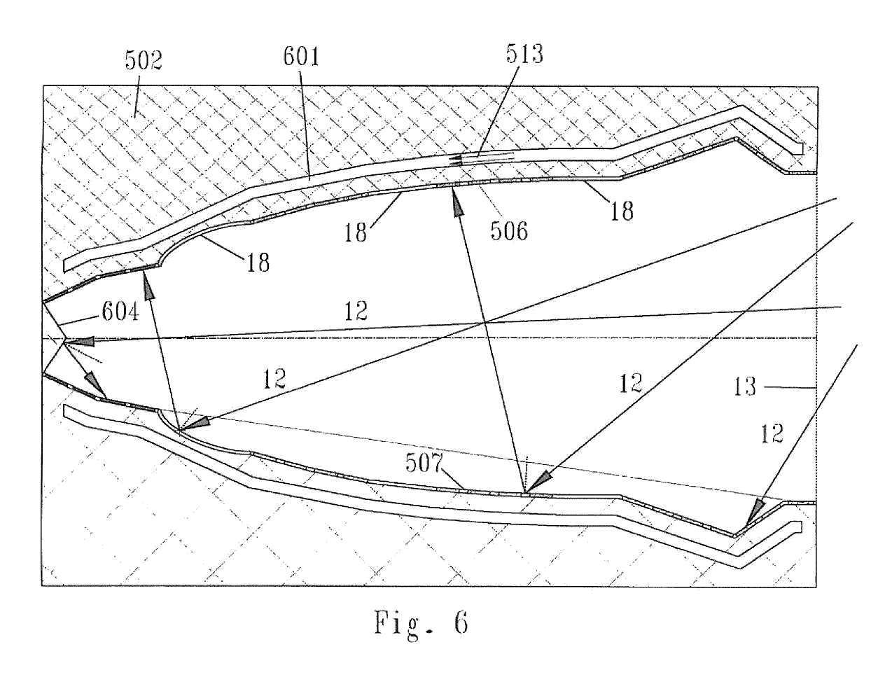

FIG. 6 depicts a detailed side section view of the preferred embodiment showing the invention's principal elements and five possible interaction modes with the incident irradiation.

The flux tailored cavity is housed in a structural body 502 that may be manufactured of aluminium, however other structural materials such as: steel, magnesium, titanium, carbonfibre/epoxy matrix are also possible. A circumferential integral channel 601 surrounds the irradiated volumetric surface enabling a continuous cooling fluid flow 513, said cooling flow absorbing and removing the into heat converted fraction of the irradiation energy.

The rate of the cooling fluid is monitored and controlled by a processing unit in order to ensure that the structural body and photon conversion devices operate at their optimal temperatures and do not exceed the maximum operating limits. Said cooling fluid may be: water, a water/alcohol mixture, oil, compressed air or any other fluid substance having the required physical, thermodynamic and chemical characteristics meeting the system requirements.

It is a specific intention of the present invention to further utilize the heat absorbed by the cooling fluid for additional applications such as, but not limited to: space heating of buildings, industrial process heat, private and industrial hot water generation, low heat chemical reactions, pre-heating of vapor generation fluids, chemical heat pumps, desalination of water, chemical air conditioning units, flash vaporization, swimming pool heating. The further utilization of the heated cooling fluid in secondary applications maximizes the radiation to usable energy conversion efficiency.

FIG. 6 additionally shows a possible schematic cross sectional area distribution and combination of photonic active 19 and specular reflective axial bands 18. The photonic active bands 19 are depicted with a crosshatch. The de facto combination of the axial radius distribution, axial range of the photonic active bands, geometry and size of the specular reflective segments is determined by numerical analysis, statistical ray tracing and energy conversion optimization algorithms for each exclusive combination of radiation source and concentrator system. A flux tailored cavity for the case of a radiation source with a large angular ray distribution combined with a weakly concentrating primary parabolic having a large surface error is significantly different from the case of quasi collimated source radiation combined with a strongly concentrating two stage parabolic/non-imaging concentrator.

Primary cavity-radiation modes of interactions are:
(i) An incident ray 12 impinges the photon conversion device's photonic active area 506 and is converted into electricity 511.
(ii) An incident ray 12 impinges the photon conversion device's photonic active area 506 and is converted into heat 512, subsequently absorbed by the above mentioned cooling fluid 513 and is conveyed to a remote heat exchanger.
(iii) An incident ray 12 impinges the photon conversion device's specularly reflective clad area 507, undergoes specular reflection in accordance with Snell's law, and is further propagated into the cavity for eventual absorption by an extra photon conversion device.
(iv) An incident ray 12 impinges a specularly reflective band 18 of the tailored cavity, said reflective band may have further flux boosting capabilities, undergoes specular reflection in accordance with Snell's law, is further propagated into the cavity and is eventually absorbed by a photon conversion device.
(v) An incident ray 12, with a typically low incidence angle, impinges directly the reflective base diffuser 604, undergoes specular reflection and is eventually absorbed by a photon conversion device.

A small fraction of the incident radiation may undergo multiple specular reflections within the cavity without being neither converted into electricity nor into heat, and may be re-reflected back through the mono ingress aperture 13. It is one of the primary purposes of the present invention to minimize said re-reflection losses by specifically tailoring the cavity parameters to the characteristics of the incident radiation.

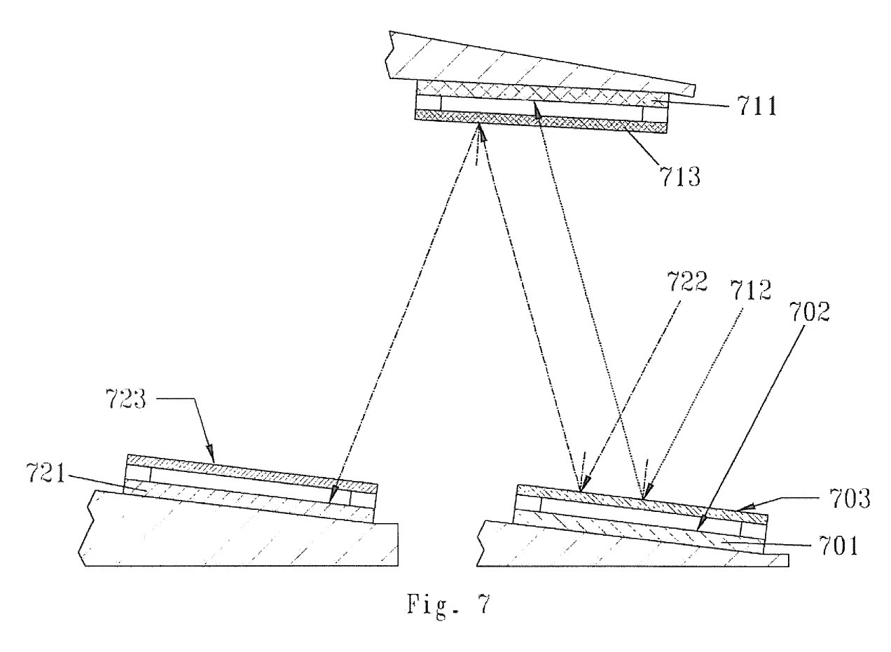

FIG. 7 depicts schematically a second preferred embodiment of the tailored volumetric cavity wherein it is clad with a plurality of photon conversion devices having different specific delimited energy bandgaps, with a combined total bandgap range spanning a large fraction of wavelength spectrum of the incident radiation, as an alternative to using monolithic multijunction photon conversion devices. The incident radiation spectrum is considered to consist of a sum of n wavelength bands: 12a (n=1), 12b (n−1) and 12c (n). The multitude of installed photon conversion devices are divided into families: 701, 711 and 721, each family having an energy bandgap corresponding to the incident radiation's photon energy. Said photon conversion devices are windowed with thin optically coated quartz, 703, 713, 723, having delimited transmissive and reflective properties; the window's transmission wavelength being closely matched to the photon conversion device's energy bandgap. Said window may be either flat or cambered. Irradiation with a wavelength in the window's transmissive band illuminates the photon conversion device and the impinging radiation energy is either converted into electricity or heat. A certain small fraction of the illuminating radiation is reflected at the photon conversion devices surface and is redirected towards the other receptive photon conversion devices in the cavity. Impinging radiation with a wave length outside of the window's transmission band is specularly reflected at the window's optical top coating and further propagated in the cavity until eventually absorbed by a photon conversion device having an energy bandgap matching the incident radiation's photon energy.

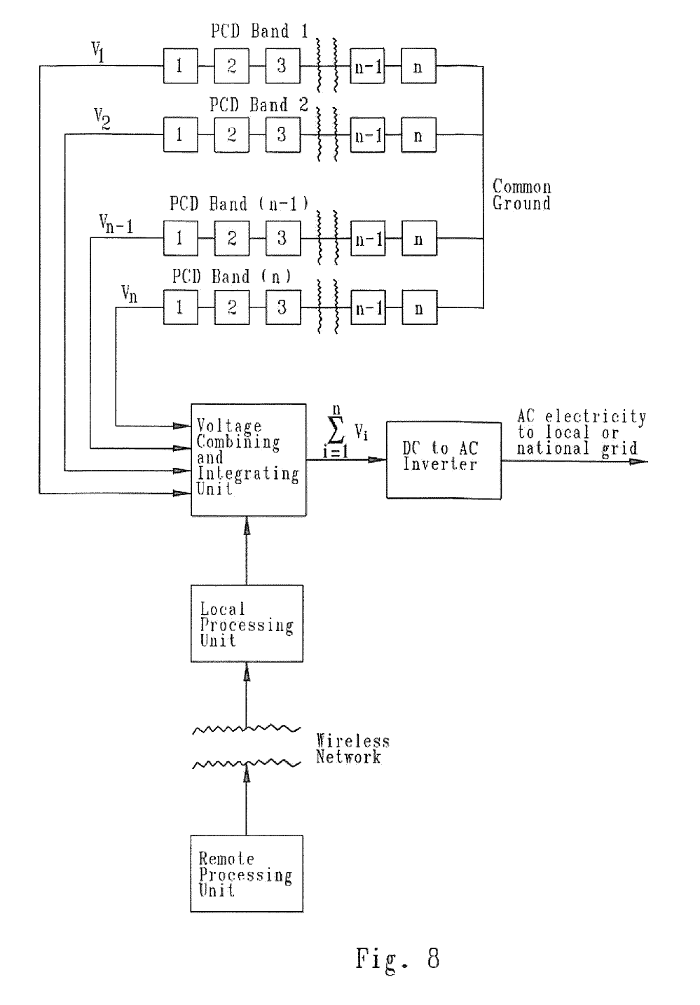

FIG. 8 depicts a preferred architectural electrical connection scheme and a possible methodology for optimizing the evacuated electrical power from the preferred embodiment.

The photon conversion device generated DC voltage is approximately a logarithmic function of the radiation flux concentration, and a voltage difference may exist between different circumferential photon conversion device band cladding the irradiated cavity; the electrical voltage being a function of the band's axial location in the cavity and the bandgap energy of the photon conversion devices in each radiation band. The tailored volumetric cavity is considered to consist of n separate irradiation bands. In each individual irradiation band the photon conversion devices are mutually interconnected and referenced to a common ground. The generated electrical power from each irradiation band is evacuated separately to a VCIU (Voltage Combining and Integrating Unit), partly consisting of a plurality of internal switching devices. The primary objective of the VCIU is to optimally integrate the separately inputted electrical power feeds into a single DC output feed with a specifically maximized electrical power level.

The power maximized output of the VCIU may be fed into a commercial DC-AC inverter for the purpose of converting the DC electricity into AC (Alternating Current) electricity with characteristics corresponding to the intended user's requirements. The hereinabove described AC electricity may be fed into the local/national electricity network or utilized as a single unique source of AC electricity. Should an end user specifically require DC current for its intended purposes (for example: industrial chemical processes, electrolysis, etc.) the DC-AC inverter may be omitted and the generated DC current conveyed directly to the end user.

The VCIU may be numerically controlled by an LCU (Local Processing Unit) incorporating an optimizing algorithm for the purpose of controlling the VCIU's internal switching combination obtaining the maximum combined electrical power output. Said switching combination may vary both with regards to: local time, season, atmospheric conditions, geography etc., and it is a specific purpose of the LCU to continuously acquire a multitude of internal and external sensor readings for the purpose of calculating the VCIU's optimal switching scheme.

The LCU may contain a device for communicating with a remote processing/control unit by means of either a wired or a wireless network; said network may be the Internet. This is specifically pertinent if the electricity generating unit is located in a remote region, is difficult to otherwise access or if an array of electricity generating units are employed in the generation of electricity.

While the invention has been described with respect to a limited number of embodiments, these should not be construed as limitations on the scope of the invention, but rather as exemplifications of some of the preferred embodiments. Those skilled in the art will envision other possible variations, modifications, and applications that are also within the scope of the invention. Accordingly, the scope of the invention should not be limited by what has thus far been described, but by the appended claims and their legal equivalents.

1. A flux tailored volumetric photon conversion device system for the purpose of converting concentrated incident radiation energy into electricity, characterized in that it comprises:
a three dimensional windowed, hollow, body of revolution, comprising a cavity of a generally optimized shape;
a plurality of photon conversion devices cladding said cavity for the purpose of converting impinging radiation energy into electricity;
a matrix of specularly reflective material cladding photonic inactive regions of said cavity for the purpose of reflecting radiation energy onto photonic active regions;
a radiation concentrator capable of continuously conveying collected concentrated radiation energy onto the ingress window of the aforementioned three dimensional body of revolution;
a unit for optimally combining a plurality of inputted current feeds into a single, power maximized, output current feed.

2. Conversion device system as claimed in claim 1, characterized in that said flux tailored volumetric cavity comprises at least one ingress aperture with the approximately largest cross sectional area of the flux tailored volumetric cavity, the diameter of said ingress aperture simultaneously optimized for minimizing re-radiation energy losses and intercepting a maximum fraction of the upon the ingress aperture impinging concentrated radiation energy.

3. Conversion device system as claimed in claim 1, characterized in that said flux tailored cavity's limiting surface is defined by at least one geometric curve being piecewise revolved 2π radians relative to at least one guiding axis, generating a generally axially contracting surface of revolution with a slenderness ratio, referred to the ingress aperture's diameter, exceeding unity.

4. Conversion device system as claimed in claim 1, characterized in that the slope of the surface of revolution is specifically tailored to the irradiation flux distribution purposefully generating a, within axial meridian bands, uniform surface radiation flux in said cavity.

5. Conversion device system as claimed in claim 1, characterized in that the specularly reflective regions of said cavity are optimized to simultaneously reflect and further concentrate re-reflected radiation towards photonic active areas of said cavity for eventual conversion into electricity.

6. Conversion device system as claimed in claim 1, characterized in that said photon conversion devices are bonded to the aforementioned cavity surface, said bond being either thermally or both thermally and electrically conductive.

7. Conversion device system as claimed in claim 6, characterized in that the photonic active areas of said photon conversion devices are specifically capable of continuously converting radiation energy to electricity whilst irradiated, said photon conversion devices comprising at least one bandgap energy, wholly, or partially, matched to the irradiation's spectrum.

8. Conversion device system as claimed in claim 6, characterized in that the photonic inactive areas of said photon conversion devices are clad with a coating, said coating being specularly reflective within the full spectrum of the incident radiation.

9. Conversion device system as claimed in claim 6, characterized in that the photon conversion device's photonic active area is windowed by a substance having an alternating selective/transmissive and selective/reflective optical coating, admitting solely the fraction of the incident radiation spectrum that matches said device's energy bandgap.

10. Conversion device system as claimed in claim 4, characterized in that at least one of the uniformly irradiated axial bands of the flux tailored tailored cavity is clad with a plurality of photon conversion devices, said uniformly irradiated band may contain a mixture of different bandgap photon conversion devices, each with a separate spectral response to the irradiation's spectrum.

11. Conversion device system as claimed in claim 1, characterized in that the photon conversion devices are electrically interconnected in an optimized electrical connection scheme for minimum electrical power losses.

12. Conversion device system as claimed in claim 1, characterized in that it comprises an auxiliary non-imaging radiation concentrating device; the exit aperture of said device approximately coinciding with the flux tailored cavity's ingress aperture.

13. Conversion device system as claimed in claim 1, characterized in that said hollow body of revolution comprises means for circulating at least one cooling fluid substance for the purpose of absorbing and removing a substantial fraction of the into heat converted radiation energy to an ancillary energy converting system.

14. Conversion device system as claimed in claim 13, characterized in that said ancillary energy converting system may comprise of a heat exchanger, thermo-electrical device, a thermo-chemical device, a steam generation device, a water desalination device, a device for energizing a thermodynamic heat engine, a device for space heating, a device for refrigeration, a device for supplying hot water, a device for generating industrial process heat or a device for conveying the latent heat energy to a remote location for subsequent utilization.

15. Conversion device system as claimed in claim 1, characterized in that said photon conversion devices are optimally connected to an external voltage combining and integrating unit (VCIU) partly consisting of a plurality of internal switching devices, wherein said VCIU enables optimally integrating the separately inputted electrical power feeds into a single output feed with a specifically maximized electrical power level conducting approximately the total sum of the electrical power carried by each single input cable.

16. Conversion device system as claimed in claim 15, characterized in that a local processing unit continuously measures the electric voltage and current conveyed in the electrical cables inputted to the VCIU and determines the optimal switching and connection scheme for continuously generating a maximum electrical power output by means of an optimizing algorithm, said processing unit may be controlled remotely by a cabled or wireless local or global network.
